(19) United States
(12) Patent Application Publication
(10) Pub. No.: US 2023/0290869 A1
(43) Pub. Date: Sep. 14, 2023

(54) Dual Gate Power Semiconductor Device and Method of Controlling a Dual Gate Power Semiconductor Device

(71) Applicant: Infineon Technologies AG, Neubiberg (DE)

(72) Inventor: Roman Baburske, Otterfing (DE)

(21) Appl. No.: 18/117,789

(22) Filed: Mar. 6, 2023

(30) Foreign Application Priority Data
Mar. 8, 2022 (DE) 102022105387.3

(51) Int. Cl. H01L 29/739; H03K 17/567; H01L 27/06; H01L 29/10; H01L 29/417

(52) U.S. Cl. CPC H01L 29/7397; H03K 17/567; H01L 27/0664; H01L 29/1095; H01L 29/41741

(57) ABSTRACT

A dual gate IGBT is presented, where the active region includes a first section and a second section. Both sections may be controlled by two control signals. For example, the first section exhibits a first characteristic transfer curve, load current in dependence of the voltage of the first control signal, and the second section exhibits a second characteristic transfer curve, load current in dependence of the voltage of the first control signal. At least the second characteristic transfer curves are changeable based on the voltage of the second control signal. For a given voltage of the first control signal corresponding to a forward-conduction-state of the power semiconductor device, the change of load current in the first section observed for a given change of the voltage of the second control signal is smaller as compared to the corresponding change of the load current in the second section.

### TECHNICAL FIELD

This specification refers to embodiments of a power semiconductor device and to embodiments of a method of producing a power semiconductor device. In particular, this specification refers to a power semiconductor device having an IGBT configuration with differently designed IGBT areas and being controllable with two control signals, and to embodiments of a corresponding control method.

### BACKGROUND

Many functions of modern devices in automotive, consumer and industrial applications, such as converting electrical energy and driving an electric motor or an electric machine, rely on power semiconductor switches. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device.

Further, in case of a controllable power semiconductor device, e.g., a transistor, the load current path may be controlled by means of an insulated electrode, commonly referred to as gate electrode. For example, upon receiving a corresponding control signal from, e.g., a driver unit, the control electrode may set the power semiconductor device in one of a forward conducting state and a blocking state.

The load current is typically conducted by means of an active region of the power semiconductor device. The active region is typically surrounded by an edge termination region, which is terminated by an edge of the chip.

To achieve a certain switching behavior and/or certain charge carrier distributions in the semiconductor, e.g., related to optimizing switching energies and/or saturation voltages, second control electrodes based on which the device can be controlled in addition to first control electrodes may be provided. Such devices are typically referred to dual-gate transistors or, respectively, multi-gate transistors.

### SUMMARY

The subject-matter of the independent claims is presented. Features of exemplary embodiments are defined in the dependent claims.

According to an embodiment, a power semiconductor device comprises: a semiconductor body coupled to a first load terminal and a second load terminal; an active region with a first section and a second section, both configured to conduct a load current between the first load terminal and the second load terminal; electrically isolated from the first load terminal and the second load terminal, a plurality of first control electrodes in both the first section and the second section, and a plurality of second control electrodes in both the first section and the second section. The first control electrodes are configured to be subjected to a first control signal. The second control electrodes are configured to be subjected to a second control signal. A plurality of semiconductor channel structures are in the semiconductor body and extend in both the first section and the second section, each of the plurality of channel structures being associated to at least one of the first control electrodes, wherein the respective at least one of the first control electrodes is configured to induce an inversion channel for load current conduction in the associated semiconductor channel structure; wherein, in a forward bias state, the first section exhibits a first characteristic transfer curve, load current in dependence of the voltage of the first control signal; and the second section exhibits a second characteristic transfer curve, load current in dependence of the voltage of the first control signal, at least the second characteristic transfer curves being changeable based on the voltage of the second control signal. For a given voltage of the first control signal corresponding to a forward-conduction-state of the power semiconductor device, the change of load current in the first section observed for a given change of the voltage of the second control signal is smaller as compared to the corresponding change of the load current in the second section. Optionally, both the first and the second characteristic transfer curves may be changeable based on the voltage of the second control signal.

For example, the change of the voltage of the second control signal is a change from a voltage corresponding to a blocking state between V_{th,p} and V_{th,n}, e.g., 0 V, to a voltage corresponding to another blocking-state below V_{th,p}, e.g., −15 V, or vice versa. For example, V_{th,n} is a control threshold voltage necessary for inducing an inversion channel in the body region and may amount to, e.g., 6 V. Further, V_{th,p} can be a further control threshold, e.g., a negative voltage below which a hole channel is induced around the respective trench, i.e., an inversion channel in the drift region, and can amount to, e.g., −4 V or −1 V.

For example, said load current change in the first section is below 30%, and wherein said load current change in the second section is above 30%.

For example, the rate of change of the first characteristic output curve is positive irrespective of the voltage of the second control signal, and the rate of change of second characteristic output curve is positive or negative depending on the voltage of the second control signal.

According to a further embodiment, a power semiconductor device comprises: a semiconductor body coupled to a first load terminal and a second load terminal; an active region with a first section and a second section, both configured to conduct a load current between the first load terminal and the second load terminal; electrically isolated from the first load terminal and the second load terminal, a plurality of first control electrodes in both the first section and the second section, and a plurality of second control electrodes in both the first section and the second section, a plurality of semiconductor channel structures in the semiconductor body extending in both the first section and the second section, each of the plurality of channel structures being associated to at least one of the first control electrodes, wherein the respective at least one of the first control electrodes is configured to induce an inversion channel for load current conduction in the associated semiconductor channel structure. In the first section, a first average effective distance between (i) the channel structures controlled by the first control electrodes and (ii) the second control electrodes is greater than a corresponding second average effective distance in the second section.

According to a further embodiment, a power semiconductor comprises: a semiconductor body coupled to a first load terminal and a second load terminal; an active region with a first section and a second section, both configured to conduct a load current between the first load terminal and the second load terminal; electrically isolated from the first load terminal and the second load terminal, a plurality of first control electrodes in both the first section and the second section, and a plurality of second control electrodes in both the first section and the second section. The first control electrodes are configured to be subjected to a first control signal. The second control electrodes are configured to be subjected to a second control signal. A plurality of semiconductor channel structures are in the semiconductor body and extend in both the first section and the second section, each of the plurality of channel structures being associated to at least one of the first control electrodes, wherein the respective at least one of the first control electrodes is configured to induce an inversion channel for load current conduction in the associated semiconductor channel structure. In the second section, the voltage of the second control signal influences the inversion channels controlled by the first control electrodes.

For example, the influence of the voltage of the second control signal on the inversion channels controlled by the first control electrodes in the second section is greater than compared to the corresponding influence in the first section.

For example, the number of second control electrodes per unit area in the second section, G2/A2, is greater than the number of second control electrodes per unit area in the first section, G2/A1.

For example, the total area of the second section amounts to at least 20% of the total area of the active region.

For example, the total area of the first section amounts to at least 30% of the remaining total area of the active region not occupied by the second section.

For example, the second section surrounds the first section.

According to a further embodiment, a power semiconductor device comprises: a semiconductor body coupled to a first load terminal and a second load terminal; an active region with a second section configured to conduct a load current between the first load terminal and the second load terminal; electrically isolated from the first load terminal and the second load terminal, a plurality of first control electrodes in the second section, and a plurality of second control electrodes in the second section. The first control electrodes are configured to be subjected to a first control signal. The second control electrodes are configured to be subjected to a second control signal. A plurality of semiconductor channel structures are in the semiconductor body and extend in the second section, each of the plurality of channel structures being associated to at least one of the first control electrodes, wherein the respective at least one of the first control electrodes is configured to induce an inversion channel for load current conduction in the associated semiconductor channel structure; wherein, in the second section, the voltage of the second control signal influences the inversion channels controlled by the first control electrodes.

For example, the second section exhibits a second characteristic transfer curve, load current in dependence of the voltage of the first control signal, the second characteristic transfer curve being changeable based on the voltage of the second control signal. For a given voltage of the first control signal corresponding to a forward-conduction-state of the power semiconductor device, the resulting load current, according to the second characteristic transfer curve has (i) a first value for the second control signal having the same value as the first control signal, and (ii) a second value for the second control signal having a value corresponding to the additive inverse of the first control signal, wherein (iii) the second value of the resulting load current being at most half, or even at most one third, of the first value of the resulting load current. In some embodiments, the influence of the second control signal on the inversion channels controlled by the first control electrodes may be even greater, resulting in a second value of the resulting load current being at most ¼, or at most one ⅛, or even at most 1/12, of the first value of the resulting load current.

Further, in an example, the second section exhibits a second characteristic transfer curve, load current in dependence of the voltage of the first control signal, wherein the second characteristic transfer curves is changeable based on the voltage of the second control signal 13-22.

For example, the first control electrodes are electrically isolated from the second control electrodes.

For example, the first control electrodes are arranged in first control trenches and insulated from the semiconductor body by a first trench insulator. For example, the second control electrodes are arranged in second control trenches and insulated from the semiconductor body by a second trench insulator. For example, the semiconductor channel structures are arranged in mesas of the semiconductor body, the mesas being laterally confined at least by the control trenches.

For example, in the second section, at least some of the mesas are laterally confined by one of the first control trenches and by one of the second control trenches.

For example, at least some of the semiconductor channel structures comprise a respective source region of a first conductivity type electrically connected to the first load terminal, wherein in the second section said source regions are arranged adjacent to the first control electrodes and spatially displaced from the second control electrodes.

For example, a barrier region is arranged between the semiconductor channel structures and a drift region of the power semiconductor device, wherein the barrier region is of the same conductivity type as the drift region, and wherein an average dopant concentration of the barrier region in the first section is greater than an average dopant concentration of the barrier region in the second section.

For example, an average distance between a respective one of the first control electrodes and a respective one of the second control electrodes in the first section is greater than a corresponding average distance in the second section.

For example, a plurality of source trenches is in the first section, each source trench comprising a source electrode electrically connected to the first load terminal.

For example, an average number of source trenches arranged between adjacent semiconductor channel structures in the first section is greater than an average number of source trenches arranged between adjacent semiconductor channel structures in the second section.

For example, the semiconductor body is formed in a single semiconductor chip.

For example, the active region further comprises a third section including a subset of the second control electrodes, the third section constituting a diode section such that the power semiconductor device exhibits an RC IGBT configuration.

According to a further embodiment, a method of operating a half bridge circuit comprising a first power semiconductor device having a configuration as described in the preceding paragraph and a second power semiconductor device having a configuration as described in the preceding paragraph is presented. The method comprises: providing a first control signal to the plurality of first control electrodes of the first power semiconductor device and providing a second control signal to the plurality of the second control electrodes of the first power semiconductor device; and providing a further first control signal to the plurality of first control electrodes of the second power semiconductor device and providing a further second control signal to the plurality of the second control electrodes of the second power semiconductor device.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a horizontal projection of a power semiconductor device in accordance with one or more embodiments;

FIGS. 2A-2C schematically and exemplarily illustrates three variants of a section of a horizontal projection of a power semiconductor device in accordance with some embodiments;

FIG. 3 schematically and exemplarily illustrates a respective section of a vertical cross-section of a first section of an active region of power semiconductor devices in accordance with at least three embodiments;

FIGS. 4A-4B schematically and exemplarily illustrates two variants of a section of a vertical cross-section of a second section of an active region of power semiconductor devices in accordance with one or more embodiments;

FIG. 5 schematically and exemplarily illustrates characteristic transfer curves relating to a first section and a second section of an active region of a power semiconductor device in accordance with one or more embodiments;

FIG. 6 schematically and exemplarily illustrates a section of a vertical cross-section of a second section of an active region of power semiconductor devices in accordance with one or more embodiments;

FIG. 7 schematically and exemplarily illustrates a section of a horizontal projection of a power semiconductor device in accordance with one or more embodiments;

FIG. 8 schematically and exemplarily illustrates a diagram of a half bridge circuit in accordance with one or more embodiments;

FIG. 9 schematically and exemplary illustrates a method of controlling a half bridge circuit in accordance with one or more embodiments;

FIG. 10 schematically and exemplarily illustrates a section of a vertical cross-section of a power semiconductor device in accordance with one or more embodiments; and

FIG. 11 schematically and exemplary illustrates a method of controlling a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell (e.g., a monolithically integrated cell of two anti-serially connected diodes), a monolithically integrated transistor cell, e.g., a monolithically integrated MOSFET or IGBT cell and/or derivatives thereof. Such diode/transistor cells may be integrated in a power semiconductor module. A plurality of such cells may constitute a cell field that is arranged with an active region of the power semiconductor device.

The term “blocking state” of the power semiconductor device may refer to conditions, when the semiconductor device is in a state configured for blocking a current flow through the semiconductor device, while an external voltage is applied. More particularly, the semiconductor device may be configured for blocking a forward current through the semiconductor device while a forward voltage bias is applied. In comparison, the semiconductor may be configured for conducting a forward current in a “conducting state” of the semiconductor device, when a forward voltage bias is applied. A transition between the blocking state and the conducting state may be controlled by a control electrode or, more particularly, a potential of the control electrode

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

The present specification in particular relates to a power semiconductor device embodied as an IGBT or as an RC-IGBT, i.e., a bipolar power semiconductor transistor or a derivate thereof.

For example, the power semiconductor device described below may be implemented on a single semiconductor chip, e.g., exhibiting a stripe cell configuration (or a cellular/needle cell configuration) and can be configured to be employed as a power component in a low-, medium- and/or high voltage application.

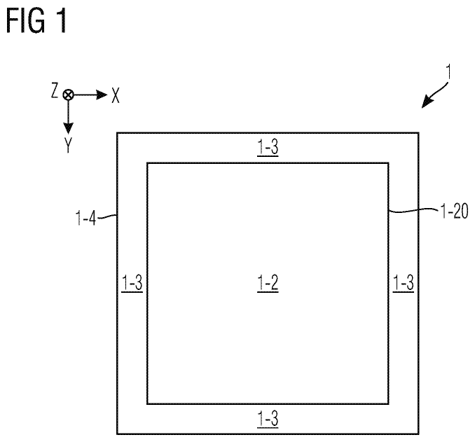

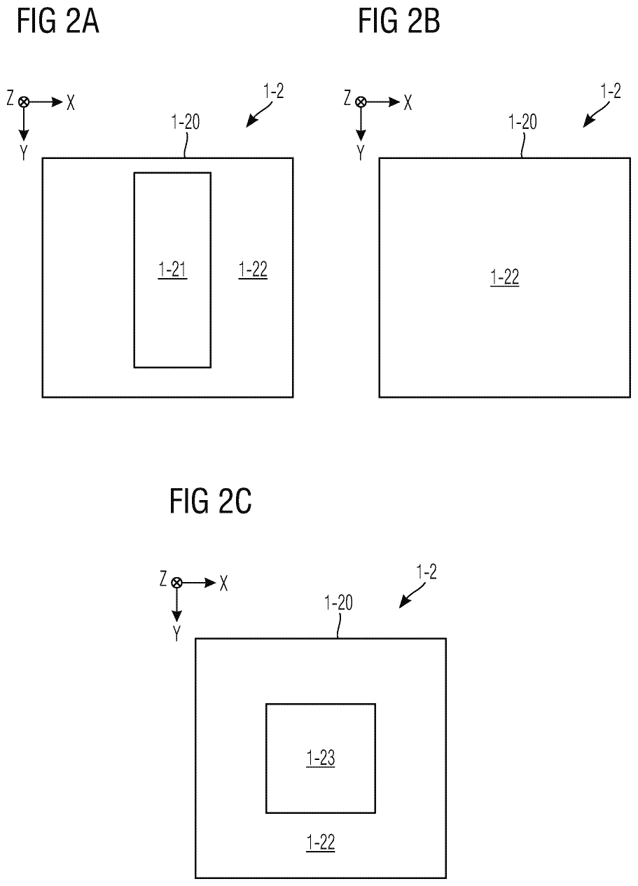

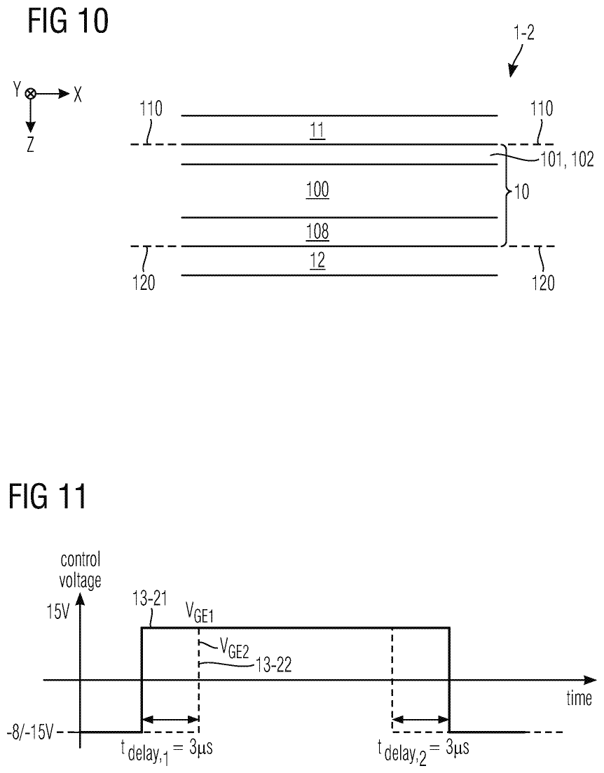

FIG. 1 illustrates a section of a horizontal projection of a power semiconductor device 1 in accordance with one or more embodiments. FIG. 10 illustrates a corresponding section of a (simplified) vertical cross-section. The power semiconductor device 1 may exhibit a MOSFET or an IGBT-configuration, for example, and comprises a semiconductor body 10 coupled to a first load terminal 11 and a second load terminal 12. The power semiconductor device 1 comprises an active region 1-2. Referring to FIG. 2A, the active region 1-2 of the power semiconductor device 1 has a first section 1-21 and a second section 1-22, both sections 1-21 and 1-22 being configured to conduct a load current between the first load terminal 11 and the second load terminal 12. Referring to FIG. 2B, the active region 1-2 of the power semiconductor device 1 has a second section 1-22, the second section 1-22 being configured to conduct a load current between the first load terminal 11 and the second load terminal 12. In the embodiment of FIG. 2B, the active region 1-2 of the power semiconductor device 1 is devoid of the first section 1-21.

As illustrated in FIG. 10, the semiconductor body 10 may be sandwiched between the first load terminal 11 and the second load terminal 12. Hence, the power semiconductor device 1 may exhibit a vertical configuration, according to which the load current, in both sections 1-21 and 1-22, follows a path substantially in parallel to the vertical direction Z.

The active region 1-2 that includes both sections 1-21 and 1-22 may be confined by a border 1-20 where the active region 1-2 transitions into an edge termination region 1-3, which is in turn terminated by a chip edge 1-4.

Herein, the terms active region and edge termination region are used in a technical context the skilled person typically associates with these terms. Accordingly, the active region's purpose is primarily to ensure load current conduction, whereas the edge termination region 1-3 is configured to reliably terminate the active region 1-2, e.g. in terms of courses of the electric field during conduction state and during blocking state.

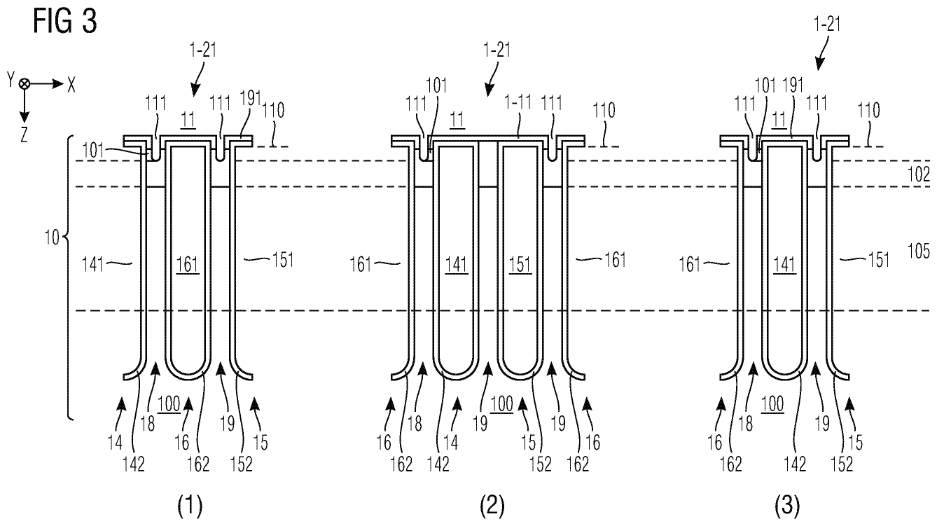

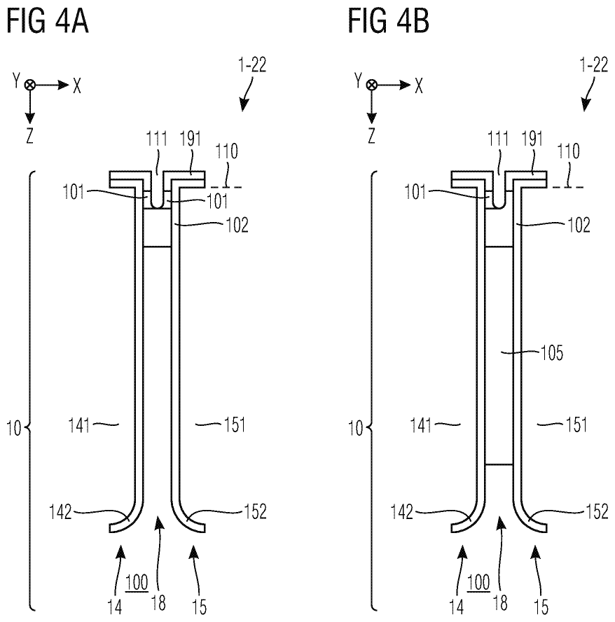

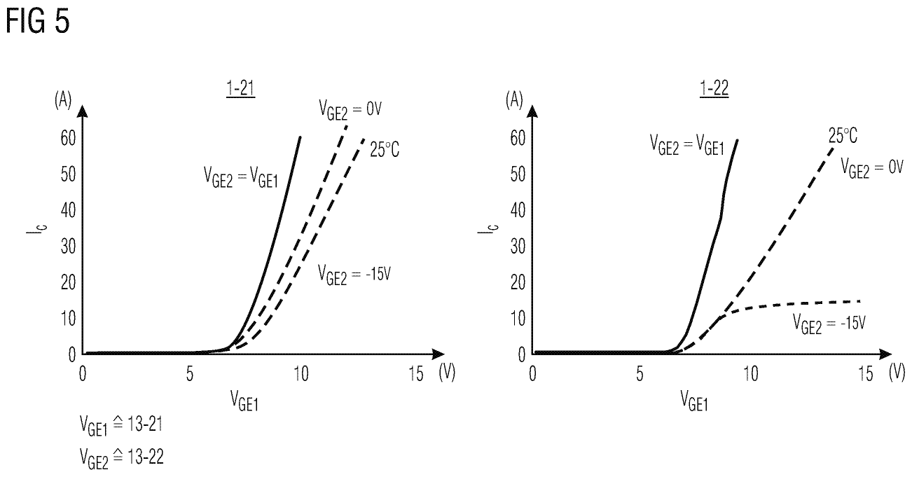

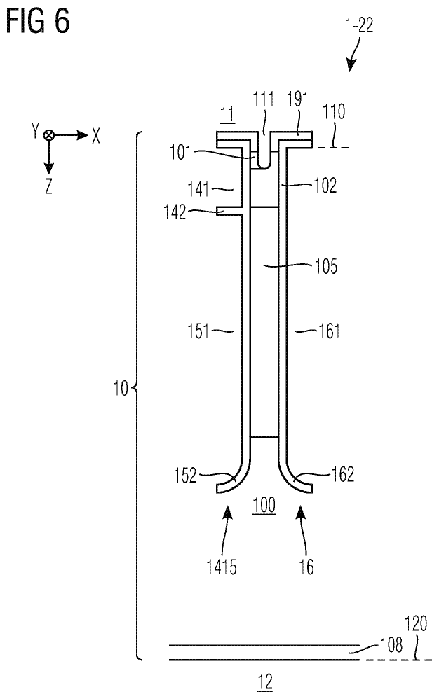

Referring additionally to FIGS. 3, 4A-4B and 6, the power semiconductor device 1 further comprises, electrically isolated from the first load terminal 11 and the second load terminal 12, a plurality of first control electrodes 141 in both the first section 1-21 and the second section 1-22 and a plurality of second control electrodes 151 in both the first section 1-21 and the second section 1-22 (cf. FIG. 3 for the first section 1-21 and FIGS. 4 and 6 for the second section 1-22).

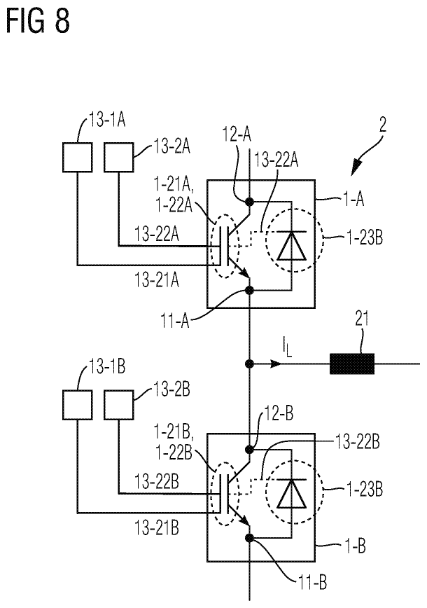

In the context of power semiconductor devices having an IGBT configuration, these control electrodes are typically referred to as gate electrodes. The control signal may be generated by applying a voltage, e.g. between the first load terminal 11 and a control/gate terminal (cf. FIG. 8, terminals 13-1A, 13-2A, 13-1B and 13-2B).

For example, each of the plurality of the first control electrodes 141 is electrically connected to at least one first control terminal 13-1A (cf. FIG. 8), and each of the plurality of second control electrodes 151 is electrically connected to at least one second control terminal 13-2A, wherein each of the at least one first control terminal 13-1A is electrically isolated from each of the at least one second control terminal 13-2A. Thereby, the first control electrodes 141 may be subjected to a first control voltage independently from the second control electrodes 151, which may be subjected to a second control voltage. For example, the first control voltage is generated as a voltage between the first control electrodes 141 (or, respectively, the first control terminal(s) 13-1A) and the first load terminal 11, and the second control voltage is generated as a voltage between the second control electrodes 151 (or, respectively, the second control terminal (s) 13-2A) and the first load terminal 11. The first control voltage may be different from the second control voltage. In another embodiment, the second control electrodes 151 are coupled to the first control electrodes 141 via an RC-structure having defined ohmic and capacitive characteristics such that the second control signal may be derived from the first control signal and only one gate terminal is needed for both the first control electrodes 141 and the second control electrodes 151.

The power semiconductor device 1 further comprises a plurality of semiconductor channel structures in the semiconductor body 10 that extend in both the first section 1-21 and the second section 1-22. Each of the plurality of channel structures is associated to at least one of the first control electrodes 141, wherein the respective at least one of the first control electrodes 141 is configured to induce an inversion channel for load current conduction in the associated semiconductor channel structure.

Each channel structure may comprise a source region 101 of the first conductivity type and a body region 102 of the second conductivity type, both electrically connected to the first load terminal 11, wherein the body region 102 isolates the source region 101 from a drift region 100 of the power semiconductor device 1, as will be explained in more detail with respect to FIGS. 3 and 4 below. Said inversion channel in the respective associated channel structure may be induced by subjecting the respective first control electrode 141 to the first control voltage.

The first section 1-21 of the active region 1-2 exhibits a first characteristic transfer curve, i.e., a characteristic load current in dependence of the voltage of the first control signal 13-21 during the forward bias state. An example of the first characteristic transfer curve is illustrated in FIG. 5, left part.

The second section 1-22 of the active region 1-2 exhibits a first characteristic transfer curve, i.e., a characteristic load current in dependence of the voltage of the first control signal 13-21 during the forward bias state. An example of the second characteristic transfer curve is illustrated in FIG. 5, right part.

Since, in an embodiment (cf. FIG. 2A, the second control electrodes 152 are present in both the first section 1-21 and the second section 1-22, at least the second characteristic transfer curves are changeable based on the voltage of the second control signal 13-22. Optionally, both the first and the second characteristic transfer curves may be changeable based on the voltage of the second control signal 13-22.

In an embodiment, for a given voltage of the first control signal corresponding to a forward-conduction-state of the power semiconductor device, the change of load current in the first section observed for a given change of the voltage of the second control signal 13-22 is smaller as compared to the corresponding change of the load current in the second section 1-22. This exemplary difference between the first section 1-21 and the second section 1-22 is illustrated in FIG. 5, for a junction temperature of 25° C. Accordingly, the change of the voltage of the second control signal 13-22 (V_{GE2}) can be a change from a voltage corresponding to a blocking state between V_{th,p} and V_{th,n}, e.g., 0 V, to a voltage corresponding to another blocking-state below V_{th,p}, e.g., −15 V or −8V, or vice versa.

If present, in the first section 1-21 (left part of FIG. 5), such change of the second control signal 13-22 (V_{GE2}) has comparatively little influence on the first characteristic transfer curve; the threshold voltage is increased a little bit and the rate of change of the load current I_{C} over the voltage of the first control signal 13-21 (V_{GE1}) is decreased compared to the case where the second control signal 13-22 (V_{GE2}) is identical, in terms of voltage value, to the first control signal 13-21 (V_{GE1}) or, respectively, 0 V.

By contrast, due to the design of the second section 1-22, examples of which being explained further below, such change of the voltage of the second control signal 13-22 (V_{GE2}) from, e.g., 0 V to −15 V has a significant influence on the second characteristic transfer curve: There, the rate of change of the current I_{C} over the voltage of the first control signal 13-21 (V_{GE1}) reaches a maximum, and thereafter, the load current I_{C} increases only slightly with increasing voltage of the first control signal 13-21 (V_{GE1}). For example, for a give voltage of the first control signal 13-21 (V_{GE1}), e.g., 15 V, said load current change in the first section 1-21 is below 40%, e.g., below 30% or 20%, and said load current change in the second section 1-22 is above 30%, or even above 40%, e.g., above 75%, e.g., above 100%.

Regarding the aforesaid, it shall be understood that the change of the voltage of the second control signal 13-22 (V_{GE2}) from 0 V to the value of the voltage of the first control signal 13-21 (V_{GE1}), i.e., V_{GE2}=V_{GE1}, was one illustrative example. For both sections 1-21 and 1-22, source regions 101 may be arranged adjacent to the second control signal; thus, if the voltage of the second control signal 13-22 (V_{GE2}) exceeds the threshold value V_{th,n}, further electrons may be injected, which in some applications may be desirable, and in other applications shall be avoided. Accordingly, in FIG. 4A, the source region 101 is arranged both adjacent to the first control trench 14 and the second control trench 15 (with a corresponding influence of the voltage of the second control signal 13-22 (V_{GE2}) onto the electron injection), in FIG. 4B, in the mesa 18, the source region 101 is arranged only adjacent to the first control trench 14 but not adjacent the second control trench 15 (with a correspondingly reduced influence of the voltage of the second control signal 13-22 (V_{GE2}) onto the electron injection).

In more general words, referring to FIG. 5, right part/second section 1-22, the second section 1-22 in an embodiment exhibits a second characteristic transfer curve (i.e., load current in dependence of the voltage of the first control signal 13-21 (V_{GE1})), wherein the second characteristic transfer curve is changeable based on the voltage of the second control signal 13-22 (V_{GE2}). For a given voltage of the first control signal 13-21 (V_{GE1}) corresponding to a forward-conduction-state of the power semiconductor device, the resulting load current, according to the second characteristic transfer curve has (i) a first value for the second control signal having the same value as the first control signal (V_{GE1}=V_{GE2}), and (ii) a second value for the second control signal having a value corresponding to the additive inverse of the first control signal (e.g., V_{GE2}=−V_{GE2}, cf. lower dashed line), wherein (iii) the second value of the resulting load current being at most half, or even at most one third, of the first value of the resulting load current, as exemplarily illustrated in FIG. 5.

In an embodiment, a first average effective distance, in the first section 1-21, between (i) the channel structures controlled by the first control electrodes 141 and (ii) the second control electrodes 151 is greater than a corresponding second average effective distance in the second section 1-22. Thereby, the effect of the voltage of the second control signal 13-21 (V_{GE2}) in the first section 1-21 may be reduced compared to the effect observed in the second section 1-22, e.g., in a manner as described above. More specific implementation examples will be described below.

Referring to FIGS. 4A and 4B, said average effective distances are depending on the width of the mesa 18; the wider the mesa 18, the greater the distance between the channel structures (in the body region 102) controlled by the first control electrodes 141 and the second control electrode 151. For example, the width of the mesa 18 (i.e., the average distance between the adjacent trench insulators 142, 152 along the first lateral direction X) may be smaller than 2 μm, smaller than 1.5 μm or even smaller than 700 nm. Alternatively or additionally, the average effective distances may be modified based on the dopant concentration in the mesa 18, e.g., based on providing said barrier region 105 of the first conductivity type, which may optionally be implemented and may exhibit a dopant concentration significantly greater than the dopant concentration of the drift region 100. The higher the dopant concentration of the barrier region 105, the higher the average effective distance between the source region 101 and the second control electrode. For example, the dose of the barrier region 105 may amount to 1*10¹³ cm⁻². If such barrier region is present, the above-mentioned physical mesa widths (“smaller than 2 μm, smaller than 1.5 μm or even smaller than 700 nm”) could be reduced to smaller than 1.5 μm, smaller than 700 nm or even smaller than 400 nm without changing the average effective distance compared to the case where no barrier region 105 is implemented.

In another embodiment, in the second section 1-22, the voltage of the second control signal 13-22 (V_{GE2}) influences the inversion channels controlled by the first control electrodes 141, e.g., as described above and illustrated in FIG. 5, right part. For example, the influence of the voltage of the second control signal 13-22 (V_{GE2}) on the inversion channels controlled by the first control electrodes 141 in the second section 1-22 is greater than compared to the corresponding influence in the first section 1-21. Said inversion channels may refer to the hole channels around the first and second control trenches 14, 15 in the drift region 100.

For example, the total area of the second section 1-22 amounts to at least 10%, to at least 20%, 30% or to at least 45% of the total area of the active region 1-2. Or, the total area of the second section 1-22 is within the range of 70% to 130% of the total area of the first section 1-21. The total area of the first section 1-21 may amount to at least 30% of the remaining total area of the active region 1-2 not occupied by the second section 1-22. The second section 1-22 may surround the first section 1-21, as illustrated in FIGS. 2A through 2C.

Here, it shall be noted that, beyond sections 1-21 and 1-22, the power semiconductor device may include, in its active region 1-2, further sections, e.g., sections similarly configured as section 1-22, but in which the difference compared to section 1-21 is implemented to a lesser or higher degree. For example, in a first variation of the second section 1-22 the maximum of the rate of change of the current I_{C} over the voltage of the first control signal 13-21 (V_{GE1}) is reached at 20% of the nominal load current I_{C}, and in a second variation of the second section 1-22 the maximum of the rate of change of the current I_{C} over the voltage of the first control signal 13-21 (V_{GE1}) is reached at 50% of the nominal load current I_{C}, and in a third variation of the second section 1-22 the maximum of the rate of change of the current I_{C} over the voltage of the first control signal 13-21 (V_{GE1}) is reached at 150% of the nominal load current I_{C}.

The above described embodiments include the following recognitions: the active region 1-2 of the power semiconductor device 1 may be divided into one or more first sections 1-21 and one or more second sections 1-22, wherein these spatially distinct sections may be configured differently to achieve desirable switching properties of the power semiconductor device 1. Both sections 1-21 and 1-22 are controlled based on both control signals, wherein the second control signal has less effect on the first section 1-21 as compared to the second section 1-22, for example when changing the value of the voltage of the second control signal around V_{th,p}, e.g., from 0 V to −8 V or vice versa. According to some embodiments, both sections 1-21 and 1-22 are controlled based on both control signals, wherein the second control signal has less effect on the first section 1-21 as compared to the second section 1-22, for example when changing the value of the voltage of the second control signal above V_{th,n}, e.g., from 0 V to V_{GE2}=V_{GE1} or vice versa. For example, by providing the first and second control signals not entirely synchronously, but with a time delay, advantageous switching behavior can be achieved, as will be explained in more detail below.

According to the embodiments illustrated in FIGS. 3 and 4, the first control electrodes 141 are arranged in first control trenches 14 and insulated from the semiconductor body 10 by a respective first trench insulator 142. Likewise, the second control electrodes 151 are arranged in second control trenches 15 and insulated from the semiconductor body 10 by a respective second trench insulator 152.

Further, the semiconductor channel structures are arranged in mesas 18 of the semiconductor body 10, the mesas 18 being laterally confined at least by the control trenches 14, 15.

As further illustrated, the power semiconductor device 1 according to these embodiments comprises a plurality of source trenches 16 in at least the first section 1-21 and optionally also the second section 1-22, each source trench 16 comprising a source electrode 161 electrically connected to the first load terminal 11 and insulated from the semiconductor body 10 by a respective third trench insulator 162.

The trench-mesa pattern, which is not shown in the simplified illustration of FIG. 10, is configured at a front side 110. The mesas 18 including the channel structures are electrically connected to the first load terminal 11, e.g., via first contact plugs 111. For example, in each mesa 18, the contact plug 111 is electrically connected to both the source region 101 and the body region 102.

Besides the mesas 18, the trench-mesa pattern may include a second type mesa 19 not comprising a source region 101 and which may be connected to the first load terminal 11 (cf. FIG. 3, variants (1) to (3)) or not (cf. FIG. 3, variant (2), middle mesa 19). However, also the second type of mesa 19 may be equipped with a section of the body region 102, as illustrated.

Optionally, between the body region 102 and the drift region 100, there may be arranged a barrier region 105. Both the barrier region 105 and the drift region 100 are of the first conductivity type, wherein the dopant concentration of the barrier region 105 may be greater than compared to the drift region's dopant concentration.

Briefly also referring to FIG. 10, the drift region 100 extends along the vertical direction Z until interfacing with said emitter region 108 of the second conductivity type that is electrically connected to the second load terminal 12, in accordance with one or more embodiments.

The trench-mesa pattern in the first section 1-21 may be variously configured, some examples being now presented: For example, referring to FIG. 3, variant (1), mesa 18 is laterally confined by one of the first control trenches 14 and one of the source trenches 16, but not by one of the second control trenches 15. Together with said source trench 16, the second control trench 15 laterally confines the second type mesa 19. The second type mesa 19 may or may not include a source region 101. Similarly, in variant (2), mesa 18 is laterally confined by one of the first control trenches 14 and one of the source trenches 16, but not by one of the second control trenches 15. Together with the first control trench 14, the second control trenches laterally confines a second type mesa 19 not electrically connected to the first load terminal 11 (i.e., acting as a dummy mesa) and, together with the source trench, a second type mesa 19 electrically connected to the first load terminal 11. Variant (3) corresponds to variant (1) with the positions of the first control trench 14 and the source trench 16 interchanged. In each of the illustrated three variants, the second control electrode 151 is not arranged adjacent to the mesa 18 where the inversion channel is induced by the first control electrode 141. According to the embodiments illustrated in FIG. 3, the first type mesa 18 includes the source region 101 to allow the injection of charge carriers of the first conductivity type, e.g., electrons in case of an n-type source region 101, into the inversion channel next to the first control electrode 141. Within the second type mesa 19, a further conductive channel may be formed, when the voltage of the second control signal (V_{GE2}) at the second control electrode 151 has a value corresponding to a low level (e.g. −15 V) of the second control signal V_{GE2}. Said further conducting channel may consist, at least predominantly, of charge carriers of the second conductivity type, e.g., holes.

In the second section 1-22, as illustrated in FIGS. 4A and 4B, both one of the first control trenches 14 and one of the second control trenches 15 may laterally confined the mesa 18. Due to the smaller distance between the inversion channel and the second control electrode 151, the influence of the second control signal 13-22 on the course of the second characteristic transfer curve of the second section 1-22 is greater than compared to its influence on the course of the first characteristic transfer curve of the first section 1-21.

In an embodiment, the number of second control electrodes 151 per unit area in the second section 1-22, G₂/A₂, is greater than the number of second control electrodes (151) per unit area in the first section 1-21, G₂/A₁. For example, by this measure, it may be provided that in the first section 1-21, said first average effective distance between (i) the channel structures controlled by the first control electrodes 141 and (ii) the second control electrodes 151 is greater than a corresponding second average effective distance in the second section 1-22.

A further option to achieve the reduced influence of the second control signal within the first section 1-21 is to correspondingly laterally structure the barrier region 105, as has been explained above with respect to FIGS. 4A and 4B. For example, an average dopant concentration of the barrier region 105 in the first section 1-21 is greater than an average dopant concentration of the barrier region 105 in the second section 1-22. As the barrier region 105 can be considered as being arranged “between” the inversion channel in mesa 18 and the second control electrode 152, a higher dopant concentration of the barrier region 105 yields to a greater resistivity for the holes and consequently to an increase of the effective distance between (i) the channel region in the source region 101 adjacent to the first control 141 and (ii) the second control electrode 151 in the second control trench 15. Another option to achieve the reduced influence of the second control signal within the first section 1-21 is to ensure that an average distance between a respective one of the first control electrodes 141 and a respective one of the second control electrodes 151 in the first section 1-21 is greater than a corresponding average distance in the second section 1-22. A yet further option is to ensure that an average number of source trenches 16 arranged between adjacent semiconductor channel structures in the first section 1-21 is greater than an average number of source trenches 16 arranged between adjacent semiconductor channel structures in the second section 1-22. A yet further option to modulate the degree of influence of the second control signal is that the average ratio between the trench insulator thickness 142 and 152 is lower in the first section 1-21 compared to the second section 1-22. For example, in the second section 1-22, the thickness of the second trench insulator 152 may smaller as in the first section 1-22, and the thickness of first trench insulator 142 in the second section 1-22 may be the same as in the first section 1-21.

Referring to FIG. 6, in the second section 1-22, the first control electrode 141 and the second control electrode 151 may even be provided in the same trench 1415. As the first control electrodes 141 is subjected to the first control signal 13-21 and the second control electrode 151 is subjected to the second control signal 13-22 different from the first control signal 13-21, insulation of the two control electrodes 141, 151 within trench 1415 must be ensured based on a corresponding configuration of the first and second trench insulators 142, 152. The first control electrode 141 is arranged in an upper section of the trench 1415, in vicinity to the source region 101. The second control electrode 152 is arranged below the first control electrode 141. For example, the border between said two control electrodes 141, 151 can be arranged at the vertical level where the body region 102 interface with the barrier region 105 (if present) or, respectively, with the drift region 100 (in case no barrier region 105 is implemented).

Referring to each of FIGS. 3, 4 and 6, an insulation layer 191 may be provided at the first side 110 for local electrical insulation between the first load terminal 11 and the semiconductor body 10.

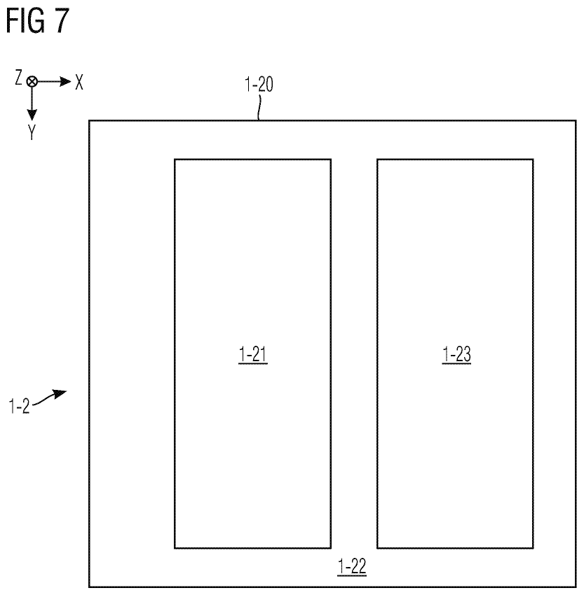

In an embodiment, referring to FIG. 7, the active region 1-2 may further comprise a third section 1-23 including a subset of the second control electrodes 151. For example, the third section 1-23 constitutes a diode section such that the power semiconductor device (1) exhibits an RC IGBT configuration. In a region at the second side 120 corresponding to a vertical projection of the illustrated third section 1-23, the semiconductor body 10 may be configured accordingly, e.g., by exhibiting, instead of the emitter region 108 of the second conductivity type, regions of the first conductivity type electrically connected to the second load terminal 12. Hence, in addition to the first section(s) 1-21 and second section(s) 1-22, distinct diode sections may be provided in the active region 1-2, e.g., so as to provide the device 1 with improved reverse conductivity, RC, properties. Depending on the application, such distinct diode sections may form at least 10 to 35% of the active region 1-2. For example, the third section 1-23 is solely controlled based on the second control signal 13-22.

The embodiment of FIG. 2B (where there is no first section 1-21), may likewise include a third section 1-23 in the active region 1-2, cf. FIG. 2C. In the embodiment of FIG. 2C, the active region 1-2 may comprise the second section 1-22 and the third section 1-23, for example resulting in an RC IGBT as described above. For example, said embodiment may be devoid of the first region 1-21.

Irrespective of the whether the power semiconductor device 1 comprises the first section 1-21 and/or the third section 1-23 in the active region 1-2, the device may be controlled based on the first control signal 13-21 (V_{GE1}) and the second control signal 13-22 (V_{GE2}) as exemplarily illustrated in FIG. 11. For example, to turn-on the power semiconductor device 1, the voltage of the first control signal 13-21 (V_{GE1}) is changed from the low level (e.g., −8 V or −15 V) to the high level (e.g., 15 V), resulting in inducing inversion channels in the body regions 102. A little later, with a first time delay, t_{delay, 1}, also the voltage of the second control signal 13-22 (V_{GE2}) is changed from the low level (e.g., −8 V or −15 V) to the high level (e.g., 15 V). The first time delay t_{delay, 1} may for example amount to 3 μs. This results in further electron injection. The delayed “turn-on” of the second control signal may be used for the short detection. Alternatively, t_{delay, 1} may be zero/close to zero to reduce turn-on losses. Before fully turning off the device, the voltage of the second control signal 13-22 (V_{GE2}) is changed from the high level (e.g., 15 V) to the low level (e.g., −8 V or −15 V), resulting in a desaturation of the device 1 before full turn-off and hence a reduction of switching losses. With a second time delay, t_{delay, 2}, which may or may not be identical to the first time delay, the first control signal follows, i.e., is also changed from the high level (e.g., 15 V) to the low level (e.g., −8 V or −15 V), resulting in the cut of the load current.

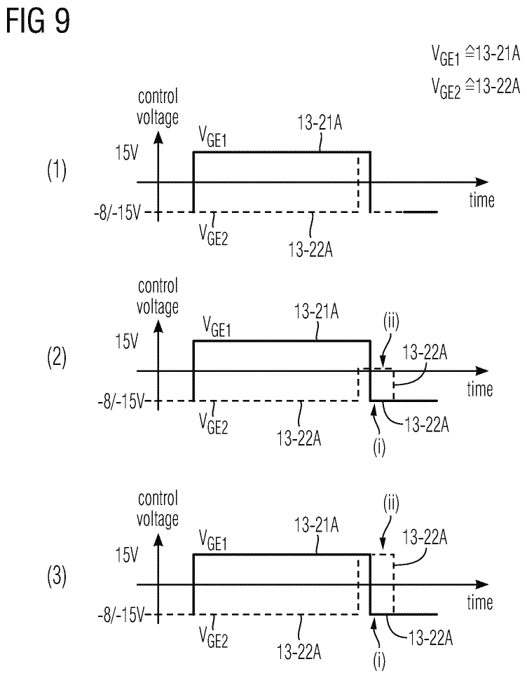

Now referring to FIGS. 8 and 9, an exemplary specific method of operating a half bridge 2 shall be described. The half bridge circuit 2 comprises a first power semiconductor device 1-A, in the following referred to as first RC IGBT 1-A, and a second power semiconductor device 1-B, in the following referred to as second RC IGBT 1-B. The first RC IGBT 1-A and the second RC IGBT 1-B may be identically configured, e.g., in accordance with one of the embodiments described above. Hence, the reference numerals used in FIGS. 8 and 9 correspond to the reference numerals used above, and are additionally provided with an ‘A’ in case the first RC IGBT 1-A is addressed, and with a ‘B’, in case of the second RC IGBT 1-B. In addition to the load terminals 11-A, 12-A, 11-B and 12-B, control terminals 13-1A, 13-2A, 13-1B and 13-2B are illustrated. These terminals are electrically connected with the respective first or second control electrodes.

Generally, the method comprises: providing a first control signal 13-21A to the plurality of first control electrodes 141 of the first RC IGBT 1-A and providing a second control signal 13-22A to the plurality of the second control electrodes 151 of the first RC IGBT 1-A, and providing a further first control signal 13-21B to the plurality of first control electrodes 141 of the second RC IGBT 1-B and providing a further second control signal 13-22B to the plurality of the second control electrodes 151 of the second RC IGBT 1-B.

For example, the first control signal 13-21A is provided as a voltage between the first control terminal 13-1A of the first RC IGBT 1-A and the first load terminal 11-A of the first RC IGBT 1-A. For example, the first control signal 13-21A is a first gate signal, e.g., provided by a (non-illustrated) driver unit.

For example, the second control signal 13-22A is provided as a voltage between the second control terminal 13-2A of the first RC IGBT 1-A and the first load terminal 11-A of the first RC IGBT 1-A. For example, the second control signal 13-22A is a second gate signal for the first RC IGBT 1-A, e.g., provided by the (non-illustrated) driver unit.

For example, the further first control signal 13-21B is provided as a voltage between the first control terminal 13-1B of the second RC IGBT 1-B and the first load terminal 11-B of the second RC IGBT 1-B. For example, the second control signal 13-21B is a first gate signal for the second RC IGBT 1-B, e.g., provided by a further (non-illustrated) driver unit.

For example, the further second control signal 13-22B is provided as a voltage between the second control terminal 13-2B of the second RC IGBT 1-B and the first load terminal 11-B of the second RC IGBT 1-B. For example, the further second control signal 13-22B is a second gate signal for the second RC IGBT 1-B, e.g., provided by the further (non-illustrated) driver unit.

Based on the control, the half bridge circuit provides a current IL to an inductive load 21. For example, the half bridge circuit 2 can be part of full bridge circuit or another circuit topology, and is configured for inverting a DC input signal (e.g., the voltage across the second load terminal 12-A of the first RC-IGBT 1-A and the first load terminal 11-B of the second RC IGBT 1-B) into an AC output signal, e.g., said current IL. For example, in each half cycle of the load current IL, one of the two RC IGBTs 1-A, 1-B is in diode/reverse operation and the other one is in IGBT/forward operation; after each half cycle, the operation changes from diode/reverse operation to IGBT/forward operation or, respectively, from IGBT/forward operation to diode/reverse operation.

For example, in each half cycle of the current IL, one of the two RC IGBTs 1-A, 1-B is in diode/reverse operation and the other one is in IGBT/forward operation; after each half cycle, the operation changes from diode/reverse operation to IGBT/forward operation or, respectively, from IGBT/forward operation to diode/reverse operation.

For example, the RC IGBT 1-A/1-B of the half bridge circuit 2 being in IGBT/forward operation may be controlled in a conventional manner, e.g., at least based on the first control signal 13-21A or, respectively, at least based on the further first control signal 13-21B. Additionally, the RC IGBT 1-A/1-B of the half bridge circuit 2 being in IGBT/forward operation may be controlled also based on the second control signal 13-22A or, respectively, based on the further second control signal 13-22B.

Further in accordance with embodiments described herein, the second control signal 13-22A and the further second control signal 13-22B may be provided in dependence of a current direction of the half bridge current IL. For example, the RC IGBT 1-A/1-B of the half bridge circuit 2 being in diode/reverse operation may be controlled at least based on the second control signal 13-22A or, respectively, at least based on the further second control signal 13-22B that may both be generated in dependence of a current direction of the current IL. Additionally, the RC IGBT 1-A/1-B of the half bridge circuit 2 being in diode/reverse operation may be controlled also based on the first control signal 13-21A or, respectively, based on the further first control signal 13-21B.

The method may hence further comprise detecting a direction of a half bridge load current IL and providing both the first plasma control signal 13-22A and the second plasma control signal 13-22B in dependence of the detected load current direction.

The control schemes illustrated in FIG. 9 relate to the case where the first RC IGBT 1-A is in diode operation and the second RC IGBT 1-B is in IGBT operation. For example, the second control signal 13-22A may be provided such it triggers a desaturation operation prior at an end of an on-pulse defined by the first control signal 13-21A.

For example, the desaturation operation is triggered based on an on-pulse of the second control signal 13-22A. FIG. 9 shows some variants (1)-(3) of such on-pulse (which hence can be considered as a desaturation pulse). For example, the on-pulse of the first plasma control signal 13-22A is within a time frame defined by the on-pulse of the first control signal 13-21A (cf. variant (1), variant (2)-(i) and variant (3)-(i)) For example, the duration of the on-pulse of the second control signal 13-22A amounts to less than 30% or less than 10% of the duration of the on-pulse of the first IGBT control signal 13-21A (cf. all variants in FIG. 9).

The desaturation durations may depend on the thickness of the semiconductor body 10. For example, the desaturation duration, in μs, has an amount in the range of the semiconductor body thickness d (in μm) divided by 50 to the semiconductor body thickness d (in μm) divided by ten.

Further, the on-pulse of the second control signal 13-22A may terminate at the same point of time as the on-pulse of the first control signal 13-21A (cf. variant (1), variant (2)-(i) and variant (3)-(i)). Further, the on-pulse of the second control signal 13-22A can exhibit the same magnitude as the on-pulse of the first control signal 13-21A. Or, the on-pulse of the second control signal 13-22A supersedes a time frame defined by the on-pulse of the first control signal 13-21A (variant (2)-(ii) and variant (3)-(ii)) and/or exhibits a lower magnitude (e.g., lower than 70% or lower than 55%) as the on-pulse of the first control signal 13-21A (cf. variant (2)-(i) and variant (2)-(ii)).

In accordance with one or more embodiments, the half bridge circuit 2 is operated at a switching frequency, wherein the relationships between the control signals 13-21A/B, 13-22A/B as described above are obeyed in each period of the switching frequency. The switching frequency can be within the range of 100 Hz to 100 kHz.

In accordance with embodiments of the method described herein, both RC IGBTs 1-A und 1-B, when being in the IGBT/forward mode, may be controlled in a conventional way based at least on the respective first control signal 13-21A/B. Optionally, it is possible to control both RC IGBTs 1-A und 1-B, when being in the IGBT/forward mode in addition, also based on the second control signal 13-22A/B, e.g., in order to desaturate the respective RC-IGBT 1-A/B prior or after turn-off. For example, the first control signal 13-21A triggers the desaturation, and the second control signal 13-22A initializes the turn-off process. In the IGBT mode, both the respective first control signal 13-21A/B and the respective second control signal 13-22A/B may exhibit substantially identical pulse widths, the optional difference being in the time delays, wherein, as described above, also synchronous signal courses are possible, where hence the respective first control signal 13-21A/B and the second control signal 13-22A/B are identical to each other.

In accordance with embodiments of the method described herein, both RC IGBTs 1-A und 1-B, when being in the diode/reverse mode, may be controlled in a conventional way based at least on the respective first control signal 13-21A/B. For example, the first control signal 13-21A is an inverted version of the further first control signal 13-21B (obeying dead-times). Optionally, it is possible to control both RC IGBTs 1-A und 1-B, when being in the diode/reverse mode, also based on the respective second control signal 13-22A/B, e.g., in order to desaturate the respective RC-IGBT 1-A/B around turn-off time (cf. FIG. 9). In the diode mode, the respective first control signal 13-21A/B and the respective second control signal 13-22A/B may exhibit substantially different pulse widths. For example, pulse width of the second control signal is less than 50% or less than 30% or even less than 10% of the first control signal pulse width. Not only the pulse width may be smaller, but also the amplitude range of the second control signal compared to the IGBT control signal. The pulse of the second control signal may occur at various times around turn-off time defined by the first control signal. That is, during diode operation and based on the second control signal, a defined desaturation operation may be carried out around turn-off (based on the first control signal) of the RC IGBT. The shape of the desaturation pulse may be adjusted based on the configuration of the RC IGBT.

The method may comprise detecting the operation type (diode operation or IGBT operation) based on the half bridge load current (cf. reference numeral IL) and providing the respective second control signal either in accordance with IGBT operation scheme or in accordance with the diode operation scheme (e.g., FIG. 9) in dependence of the detected half bridge load current direction.

The differently configured sections 1-21 and 1-22 further allow for an improved handling of a short-circuit-situation, when the device 1 is in forward mode. For example, if a sudden increase of the (chip) load current is detected, the second control signal 13-22 may initially be set to a value corresponding to the blocking state of the device (e.g., to a negative voltage) such the load current is limited. The first control signal 13-21 is subsequently only also set to a value corresponding to the blocking state of the device (e.g., to a negative voltage) if the fault detection clearly indicates that a short circuit has been detected and that hence the sudden increase of the load current is not due to another reason, e.g., an oscillation on the load current.

Presented herein are also embodiments of a method of producing a power semiconductor device:

In an embodiment, a method of producing a power semiconductor device comprises forming the following components: a semiconductor body coupled to a first load terminal and a second load terminal; an active region with a first section and a second section, both configured to conduct a load current between the first load terminal and the second load terminal; electrically isolated from the first load terminal and the second load terminal, a plurality of first control electrodes in both the first section and the second section, and a plurality of second control electrodes in both the first section and the second section. The first control electrodes are configured to be subjected to a first control signal. The second control electrodes are configured to be subjected to a second control signal. A plurality of semiconductor channel structures are in the semiconductor body and extend in both the first section and the second section, each of the plurality of channel structures being associated to at least one of the first control electrodes, wherein the respective at least one of the first control electrodes is configured to induce an inversion channel for load current conduction in the associated semiconductor channel structure; wherein, in a forward bias state, the first section exhibits a first characteristic transfer curve, load current in dependence of the voltage of the first control signal; and the second section exhibits a second characteristic transfer curve, load current in dependence of the voltage of the first control signal, at least the second characteristic transfer curves being changeable based on the voltage of the second control signal. For a given voltage of the first control signal corresponding to a forward-conduction-state of the power semiconductor device, the change of load current in the first section observed for a given change of the voltage of the second control signal is smaller as compared to the corresponding change of the load current in the second section. Optionally, both the first and the second characteristic transfer curves may be changeable based on the voltage of the second control signal.

In a further embodiment, a method of producing a power semiconductor device comprises forming the following components: a semiconductor body coupled to a first load terminal and a second load terminal; an active region with a first section and a second section, both configured to conduct a load current between the first load terminal and the second load terminal; electrically isolated from the first load terminal and the second load terminal, a plurality of first control electrodes in both the first section and the second section, and a plurality of second control electrodes in both the first section and the second section, a plurality of semiconductor channel structures in the semiconductor body extending in both the first section and the second section, each of the plurality of channel structures being associated to at least one of the first control electrodes, wherein the respective at least one of the first control electrodes is configured to induce an inversion channel for load current conduction in the associated semiconductor channel structure. In the first section, a first average effective distance between (i) the channel structures controlled by the first control electrodes and (ii) the second control electrodes is greater than a corresponding second average effective distance in the second section.

In a further embodiment, a method of producing a power semiconductor device comprises forming the following components: a semiconductor body coupled to a first load terminal and a second load terminal; an active region with a second section configured to conduct a load current between the first load terminal and the second load terminal; electrically isolated from the first load terminal and the second load terminal, a plurality of first control electrodes in the second section, and a plurality of second control electrodes in the second section. The first control electrodes are configured to be subjected to a first control signal. The second control electrodes are configured to be subjected to a second control signal. A plurality of semiconductor channel structures are in the semiconductor body and extend in the second section, each of the plurality of channel structures being associated to at least one of the first control electrodes, wherein the respective at least one of the first control electrodes is configured to induce an inversion channel for load current conduction in the associated semiconductor channel structure; wherein, in the second section, the voltage of the second control signal influences the inversion channels controlled by the first control electrodes

In a yet further embodiment, a method of producing a power semiconductor device comprises forming the following components: a semiconductor body coupled to a first load terminal and a second load terminal; an active region with a first section and a second section, both configured to conduct a load current between the first load terminal and the second load terminal; electrically isolated from the first load terminal and the second load terminal, a plurality of first control electrodes in both the first section and the second section, and a plurality of second control electrodes in both the first section and the second section. The first control electrodes are configured to be subjected to a first control signal. The second control electrodes are configured to be subjected to a second control signal. A plurality of semiconductor channel structures are in the semiconductor body and extend in both the first section and the second section, each of the plurality of channel structures being associated to at least one of the first control electrodes, wherein the respective at least one of the first control electrodes is configured to induce an inversion channel for load current conduction in the associated semiconductor channel structure. In the second section, the voltage of the second control signal influences the inversion channels controlled by the first control electrodes.

Further embodiments of the methods presented above correspond to the embodiments of the power semiconductor device presented above. In so far, it is referred to the aforesaid.

In the above, embodiments pertaining to power semiconductor device, such as MOSFETs, IGBTs, RC IGBTs and derivatives thereof, and corresponding processing and control methods were explained. For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising”, “exhibiting” and the like are open ended terms that indicate the presence of stated elements or features, but do not preclude additional elements or features.

With the above range of variations and applications in mind, it should be understood that the present invention is not limited by the foregoing description, nor is it limited by the accompanying drawings. Instead, the present invention is limited only by the following claims and their legal equivalents.

In the following, some further embodiments are described.

Embodiment 1: A semiconductor body (10) coupled to a first load terminal (11) and a second load terminal (12);
an active region (1-2) with a first section (1-21) and a second section (1-22), both configured to conduct a respective share of the load current between the first load terminal (11) and the second load terminal (12);
electrically isolated from the first load terminal (11) and the second load terminal (12), a plurality of first control electrodes (141) in both the first section (1-21) and the second section (1-22), and a plurality of second control electrodes (151) in both the first section (1-21) and the second section (1-22), wherein:
   the first control electrodes (141) are configured to be subjected to a first control signal (13-21); and
   the second control electrodes (151) are configured to be subjected to a second control signal (13-22);
a plurality of semiconductor channel structures in the semiconductor body (10) extending in both the first section (1-21) and the second section (1-22), each of the plurality of channel structures being associated to at least one of the first control electrodes (141), wherein the respective at least one of the first control electrodes (141) is configured to induce an inversion channel for load current conduction in the associated semiconductor channel structure; wherein, in a forward bias state:
   the first section (1-21) exhibits a first characteristic transfer curve, respective share of the load current in dependence of the voltage of the first control signal (13-21);
   the second section (1-22) exhibits a second characteristic transfer curve, respective share of the load current in dependence of the voltage of the first control signal (13-21), at least the second characteristic transfer curves being changeable based on the voltage of the second control signal (13-22); and wherein
   for a given voltage of the first control signal (13-21) corresponding to a forward-conduction-state of the power semiconductor device (1), the change of load current in the first section (1-21) observed for a given change of the voltage of the second control signal (13-22) is smaller as compared to the corresponding change of the load current in the second section (1-22).

Embodiment 2: The power semiconductor device (1) of embodiment 1, wherein the change of the voltage of the second control signal (13-22) is a change from a voltage corresponding to a blocking state between V_{th,p} and V_{th,n}, e.g., 0 V, to a voltage corresponding to another blocking-state below V_{th,p}, e.g., −15 V, or vice versa.

Embodiment 3: The power semiconductor device (1) of embodiment 1 or 2, wherein said load current change in the first section (1-21) is below 30%, and wherein said load current change in the second section (1-22) is above 30%.

Embodiment 4: The power semiconductor device (1) of one of the preceding embodiments, wherein the rate of change of the first characteristic output curve is positive irrespective of the voltage of the second control signal (13-22), and the rate of change of second characteristic output curve is positive or negative depending on the voltage of the second control signal (13-22).

Embodiment 5: A power semiconductor device (1) comprising:
a semiconductor body (10) coupled to a first load terminal (11) and a second load terminal (12);
an active region (1-2) with a first section (1-21) and a second section (1-22), both configured to conduct a load current between the first load terminal (11) and the second load terminal (12);
electrically isolated from the first load terminal (11) and the second load terminal (12), a plurality of first control electrodes (141) in both the first section (1-21) and the second section (1-22), and a plurality of second control electrodes (151) in both the first section (1-21) and the second section (1-22),
a plurality of semiconductor channel structures in the semiconductor body (10) extending in both the first section (1-21) and the second section (1-22), each of the plurality of channel structures being associated to at least one of the first control electrodes (141), wherein the respective at least one of the first control electrodes (141) is configured to induce an inversion channel for contributing to the load current in the associated semiconductor channel structure; wherein
   in the first section (1-21), a first average distance parameter between (i) the channel structures controlled by the first control electrodes (141) and (ii) the second control electrodes (151) is greater than a corresponding second average distance parameter in the second section (1-22).

Embodiment 6: A power semiconductor device (1) comprising:
a semiconductor body (10) coupled to a first load terminal (11) and a second load terminal (12);
an active region (1-2) with a first section (1-21) and a second section (1-22), both configured to conduct a load current between the first load terminal (11) and the second load terminal (12);
electrically isolated from the first load terminal (11) and the second load terminal (12), a plurality of first control electrodes (141) in both the first section (1-21) and the second section (1-22), and a plurality of second control electrodes in both the first section (1-21) and the second section (1-22), wherein:
   the first control electrodes (141) are configured to be subjected to a first control signal (13-21); and
   the second control electrodes (151) are configured to be subjected to a second control signal (13-22)
a plurality of semiconductor channel structures in the semiconductor body (10) extending in both the first section (1-21) and the second section (1-22), wherein
   each of the semiconductor channel structures comprising a source region of a first conductivity type and a body region of a second conductivity type different from the first conductivity type, the body region separating the source region from a drift region of the first conductivity type; wherein
   the respective at least one of the first control electrodes (141) is configured to induce an inversion channel within the body region of the associated channel structure contributing to the load current;
   wherein, in the second section (1-22), the voltage of the second control signal (13-22) influences the inversion channels controlled by the first control electrodes (141).

Embodiment 7: The power semiconductor device (1) of embodiment 6, wherein the influence of the voltage of the second control signal (13-22) on the inversion channels controlled by the first control electrodes (141) in the second section (1-22) is greater than compared to the corresponding influence in the first section (1-21).

Embodiment 8: The power semiconductor device (1) of one of the preceding embodiments, wherein the number of second control electrodes (151) per unit area in the second section (1-22), G₂/A₂, is greater than the number of second control electrodes (151) per unit area in the first section (1-21), G₂/A₁.

Embodiment 9: The power semiconductor device (1) of one of the preceding embodiments, wherein the total area of the second section (1-22) amounts to at least 20% of the total area of the active region (1-2).

Embodiment 10: The power semiconductor device (1) of embodiment 9, wherein the total area of the first section (1-21) amounts to at least 30% of the remaining total area of the active region (1-2) not occupied by the second section (1-22).

Embodiment 11: The power semiconductor device (1) of one of the preceding embodiments, wherein the second section (1-22) surrounds the first section (1-21).

Embodiment 12: The power semiconductor device (1) of one of the preceding embodiments, further comprising a barrier region (105) arranged between the semiconductor channel structures and a drift region (100) of the power semiconductor device (1), wherein the barrier region (105) is of the same conductivity type as the drift region (100), and wherein an average dopant concentration of the barrier region (105) in the first section (1-21) is greater than an average dopant concentration of the barrier region (105) in the second section (1-22).

Embodiment 13: The power semiconductor device (1) of one of the preceding embodiments, wherein an average distance between a neighboring first control electrodes (141) and second control electrodes (151) in the first section (1-21) is greater than a corresponding average distance in the second section (1-22).

Embodiment 14: The power semiconductor device (1) of one of the preceding embodiments, further comprising a plurality of source trenches (16) in the first section (1-21), each source trench (16) comprising a source electrode (161) electrically connected to the first load terminal (11).

Embodiment 15: The power semiconductor device (1) of embodiment 14, wherein an average number of source trenches (16) arranged between adjacent semiconductor channel structures in the first section (1-21) is greater than an average number of source trenches (16) arranged between adjacent semiconductor channel structures in the second section (1-22).

Embodiment 16: A power semiconductor device (1) comprising:
a semiconductor body (10) coupled to a first load terminal (11) and a second load terminal (12);
an active region (1-2) with a second section (1-22) configured to conduct a load current between the first load terminal (11) and the second load terminal (12);
electrically isolated from the first load terminal (11) and the second load terminal (12), a plurality of first control electrodes (141) in the second section (1-22), and a plurality of second control electrodes in the second section (1-22), wherein:
   the first control electrodes (141) are configured to be subjected to a first control signal (13-21); and
   the second control electrodes (151) are configured to be subjected to a second control signal (13-22);
a plurality of semiconductor channel structures in the semiconductor body (10) extending in the second section (1-22), each of the plurality of channel structures being associated to at least one of the first control electrodes (141),
   each of the semiconductor channel structures comprising a source region of a first conductivity type and a body region of a second conductivity type different from the first conductivity type, the body region separating the source region from a drift region of the first conductivity type;
   the respective at least one of the first control electrodes (141) is configured to induce an inversion channel within the body region of the associated channel structure contributing to the load current; wherein
in the second section (1-22), the voltage of the second control signal (13-22) influences the inversion channels controlled by the first control electrodes (141).

Embodiment 17: A power semiconductor device (1) comprising:
a semiconductor body (10) coupled to a first load terminal (11) and a second load terminal (12);
an active region (1-2) with a second section (1-22) configured to conduct a load current between the first load terminal (11) and the second load terminal (12);
electrically isolated from the first load terminal (11) and the second load terminal (12), a plurality of first control electrodes (141) in the second section (1-22), and a plurality of second control electrodes in the second section (1-22), wherein:
   the first control electrodes (141) are arranged in first control trenches (14) and insulated from the semiconductor body (10) by a first trench insulator (142) and the first control electrodes (141) are configured to be subjected to a first control signal (13-21); and
   the second control electrodes (151) are arranged in second control trenches (15) and insulated from the semiconductor body (10) by a second trench insulator (152) and the second control electrodes (151) are configured to be subjected to a second control signal (13-22);
a plurality of semiconductor channel structures in the semiconductor body (10) extending in the second section (1-22), each of the plurality of channel structures being associated to at least one of the first control electrodes (141); wherein
   each of the semiconductor channel structures comprising a source region of a first conductivity type and a body region of a second conductivity type different from the first conductivity type, the body region separating the source region from a drift region of the first conductivity type;
   the respective at least one of the first control electrodes (141) is configured to induce an inversion channel within the body region of the associated channel structure contributing to the load current; wherein
   the semiconductor channel structures are arranged in mesas (18) of the semiconductor body (10), the mesas (18) being laterally confined at least by the control trenches (14, 15);
wherein, in the second section (1-22), at least some of the mesas (18) comprising channel structures are laterally confined by one of the first control trenches (14) and by one of the second control trenches (15).

Embodiment 18: The power semiconductor device (1) of one of the preceding embodiments, wherein
the second section (1-22) exhibits a second characteristic transfer curve, load current in dependence of the voltage of the first control signal (13-21), the second characteristic transfer curve being changeable based on the voltage of the second control signal (13-22), wherein
for a given voltage of the first control signal (13-21) corresponding to a forward-conduction-state of the power semiconductor device (1), the resulting load current, according to the second characteristic transfer curve, has
   a first value for the second control signal (13-22) having the same value as the first control signal (13-21), and
   a second value for the second control signal (13-22) having a value corresponding to the additive inverse of the first control signal (13-21), wherein
   the second value of the resulting load current being at most half, or even at most one third, of the first value of the resulting load current.

Embodiment 19: The power semiconductor device (1) of embodiment 18, wherein the second section (1-22) exhibits a second characteristic transfer curve, load current in dependence of the voltage of the first control signal (13-21), the second characteristic transfer curves being changeable based on the voltage of the second control signal (13-22).

Embodiment 20: The power semiconductor device (1) of one of the preceding embodiments, wherein the first control electrodes (141) are electrically isolated from the second control electrodes (151).

Embodiment 21: The power semiconductor device (1) of one of the preceding embodiments, wherein
the first control electrodes (141) are arranged in first control trenches (14) and insulated from the semiconductor body (10) by a first trench insulator (142);
the second control electrodes (151) are arranged in second control trenches (15) and insulated from the semiconductor body (10) by a second trench insulator (152);
the semiconductor channel structures are arranged in mesas (18) of the semiconductor body (10), the mesas (18) being laterally confined at least by the control trenches (14, 15).

Embodiment 22: The power semiconductor device (1) of embodiment 21, wherein, in the second section (1-22), at least some of the mesas (18) are laterally confined by one of the first control trenches (14) and by one of the second control trenches (15).

Embodiment 23: The power semiconductor device (1) of one of the preceding embodiments, wherein at least some of the semiconductor channel structures comprise a respective source region (101) of a first conductivity type electrically connected to the first load terminal (11), wherein in the second section (1-22) said source regions (101) are arranged adjacent to the first control electrodes (141) and spatially displaced from the second control electrodes (151).

Embodiment 24: The power semiconductor device (1) of one of the preceding embodiments, wherein the semiconductor body (10) is formed in a single semiconductor chip.

Embodiment 25: The power semiconductor device (1) of one of the preceding embodiments, wherein the active region (1-2) further comprises a third section (1-23) including a subset of the second control electrodes (151), the third section (1-23) constituting a diode section such that the power semiconductor device (1) exhibits an RC IGBT configuration.

Embodiment 26: The power semiconductor device (1) of embodiment 5, wherein, according to the distance parameter, the average distance between neighboring first control electrodes (141) and second control electrodes (151) in the first section (1-21) is greater than:
i. 1.75 μm if no barrier region (105) is arranged between the semiconductor channel structures and the drift region (100); or
ii. 1.25 μm if said barrier region (105) comprises a doping dose of at least 1×10¹³/cm²; or
iii. 0.8 μm if said barrier region (105) comprises a doping dose of at least 5×10¹³/cm².

Embodiment 27: The power semiconductor device (1) of embodiment 5 or 26, wherein, according to the distance parameter, the average distance between neighboring first control electrodes (141) and second control electrodes (151) in the second section (1-22) is smaller than:
i. 1.75 μm if no barrier region (105) is arranged between the semiconductor channel structures and the drift region (100); or
ii. 1.25 μm if said barrier region (105) comprises a doping dose of at most 1×10¹³/cm²; or
iii. 0.8 μm if said barrier region (105) comprises a doping dose of at most 5×10¹³/cm².

Embodiment 28: The power semiconductor device (1) of embodiment 5, wherein, according to the distance parameter, the average distance between neighboring first control electrodes (141) and second control electrodes (151) in the first section (1-21) is greater than:
i. 1.75 μm if no barrier region (105) is arranged between the semiconductor channel structures and the drift region (100); or
ii. 1.25 μm if said barrier region (105) comprises a doping concentration of at least 1×10¹⁷/cm³; or
iii. 0.8 μm if said barrier region (105) comprises a doping concentration of at least 5×10¹⁷/cm³.

Embodiment 29: The power semiconductor device (1) of embodiment 5 or 26, wherein, according to the distance parameter, the average distance between neighboring first control electrodes (141) and second control electrodes (151) in the second section (1-22) is smaller than:
i. 1.75 μm if no barrier region (105) is arranged between the semiconductor channel structures and the drift region (100); or
ii. 1.25 μm if said barrier region (105) comprises a doping concentration of at most 1×10¹⁷/cm³; or
iii. 0.8 μm if said barrier region (105) comprises a doping concentration of at most 5×10¹⁷/cm³.

What is claimed is:

1. A power semiconductor device, comprising:
a semiconductor body coupled to a first load terminal and a second load terminal;
an active region with a first section and a second section, both configured to conduct a load current between the first load terminal and the second load terminal;
electrically isolated from the first load terminal and the second load terminal, a plurality of first control electrodes in both the first section and the second section, and a plurality of second control electrodes in both the first section and the second section, wherein the first control electrodes are configured to be subjected to a first control signal and the second control electrodes are configured to be subjected to a second control signal; and
a plurality of semiconductor channel structures in the semiconductor body extending in both the first section and the second section, each of the plurality of channel structures being associated to at least one of the first control electrodes,
wherein the respective at least one of the first control electrodes is configured to induce an inversion channel for load current conduction in the associated semiconductor channel structure,
wherein, in a forward bias state:
the first section exhibits a first characteristic transfer curve, load current in dependence of a voltage of the first control signal; and
the second section exhibits a second characteristic transfer curve, load current in dependence of the voltage of the first control signal, at least the second characteristic transfer curves being changeable based on a voltage of the second control signal,
wherein for a given voltage of the first control signal corresponding to a forward-conduction-state of the power semiconductor device, the change of load current in the first section observed for a given change of the voltage of the second control signal is smaller as compared to the corresponding change of the load current in the second section.

2. The power semiconductor device of claim 1, wherein the change of the voltage of the second control signal is a change from a voltage corresponding to a blocking state between V_{th,p} and V_{th,n} to a voltage corresponding to another blocking-state below V_{th,p} or vice-versa, where V_{th,n} is a control threshold voltage for inducing an electron inversion channel and V_{th,p} is a further control threshold voltage for inducing a hole inversion channel.

3. The power semiconductor device of claim 1, wherein the load current change in the first section is below 30%, and wherein the load current change in the second section is above 30%.

4. The power semiconductor device of claim 1, wherein a rate of change of the first characteristic output curve is positive irrespective of the voltage of the second control signal, and wherein a rate of change of second characteristic output curve is positive or negative depending on the voltage of the second control signal.

5. A power semiconductor device, comprising:
a semiconductor body coupled to a first load terminal and a second load terminal;
an active region with a first section and a second section, both configured to conduct a load current between the first load terminal and the second load terminal;
electrically isolated from the first load terminal and the second load terminal, a plurality of first control electrodes in both the first section and the second section, and a plurality of second control electrodes in both the first section and the second section; and
a plurality of semiconductor channel structures in the semiconductor body extending in both the first section and the second section, each of the plurality of channel structures being associated to at least one of the first control electrodes, the respective at least one of the first control electrodes being configured to induce an inversion channel for load current conduction in the associated semiconductor channel structure,
wherein in the first section, a first average effective distance between the channel structures controlled by the first control electrodes and the second control electrodes is greater than a corresponding second average effective distance in the second section.

6. A power semiconductor device, comprising:
a semiconductor body coupled to a first load terminal and a second load terminal;
an active region with a first section and a second section, both configured to conduct a load current between the first load terminal and the second load terminal;
electrically isolated from the first load terminal and the second load terminal, a plurality of first control electrodes in both the first section and the second section, and a plurality of second control electrodes in both the first section and the second section, wherein the first control electrodes are configured to be subjected to a first control signal and the second control electrodes are configured to be subjected to a second control signal; and
a plurality of semiconductor channel structures in the semiconductor body extending in both the first section and the second section, each of the plurality of channel structures being associated to at least one of the first control electrodes, the respective at least one of the first control electrodes being configured to induce an inversion channel for load current conduction in the associated semiconductor channel structure,
wherein in the second section, a voltage of the second control signal influences the inversion channels controlled by the first control electrodes.

7. The power semiconductor device of claim 6, wherein an influence of the voltage of the second control signal on the inversion channels controlled by the first control electrodes in the second section is greater than compared to the corresponding influence in the first section.

8. The power semiconductor device of claim 6, wherein the number of second control electrodes per unit area in the second section is greater than the number of second control electrodes per unit area in the first section.

9. The power semiconductor device of claim 6, wherein the total area of the second section amounts to at least 20% of the total area of the active region.

10. The power semiconductor device of claim 9, wherein the total area of the first section amounts to at least 30% of a remaining total area of the active region not occupied by the second section.

11. The power semiconductor device of claim 6, wherein the second section surrounds the first section.

12. The power semiconductor device of claim 6, further comprising a barrier region arranged between the semiconductor channel structures and a drift region of the power semiconductor device, wherein the barrier region is of a same conductivity type as the drift region, and wherein an average dopant concentration of the barrier region in the first section is greater than an average dopant concentration of the barrier region in the second section.

13. The power semiconductor device of claim 6, wherein an average distance between a respective one of the first control electrodes and a respective one of the second control electrodes in the first section is greater than a corresponding average distance in the second section.

14. The power semiconductor device of claim 6, further comprising a plurality of source trenches in the first section, each source trench comprising a source electrode electrically connected to the first load terminal.

15. The power semiconductor device of claim 14, wherein an average number of source trenches arranged between adjacent semiconductor channel structures in the first section is greater than an average number of source trenches arranged between adjacent semiconductor channel structures in the second section.

16. A power semiconductor device, comprising:
a semiconductor body coupled to a first load terminal and a second load terminal;
an active region with a second section configured to conduct a load current between the first load terminal and the second load terminal;
electrically isolated from the first load terminal and the second load terminal, a plurality of first control electrodes in the second section, and a plurality of second control electrodes in the second section, wherein the first control electrodes are configured to be subjected to a first control signal and the second control electrodes are configured to be subjected to a second control signal; and
a plurality of semiconductor channel structures in the semiconductor body extending in the second section, each of the plurality of channel structures being associated to at least one of the first control electrodes, the respective at least one of the first control electrodes being configured to induce an inversion channel for load current conduction in the associated semiconductor channel structure,
wherein in the second section, a voltage of the second control signal influences the inversion channels controlled by the first control electrodes.

17. The power semiconductor device of claim 16, wherein:
the second section exhibits a second characteristic transfer curve, load current in dependence of a voltage of the first control signal, the second characteristic transfer curve being changeable based on the voltage of the second control signal;
for a given voltage of the first control signal corresponding to a forward-conduction-state of the power semiconductor device, the resulting load current, according to the second characteristic transfer curve, has a first value for the second control signal having the same value as the first control signal and a second value for the second control signal having a value corresponding to the additive inverse of the first control signal; and
the second value of the resulting load current is at most half of the first value of the resulting load current.

18. The power semiconductor device of claim 17, wherein the second section exhibits a second characteristic transfer curve, load current in dependence of a voltage of the first control signal, the second characteristic transfer curves being changeable based on the voltage of the second control signal.

19. The power semiconductor device of claim 17, wherein the first control electrodes are electrically isolated from the second control electrodes.

20. The power semiconductor device of claim 17, wherein:
the first control electrodes are arranged in first control trenches and insulated from the semiconductor body by a first trench insulator;
the second control electrodes are arranged in second control trenches and insulated from the semiconductor body by a second trench insulator; and
the semiconductor channel structures are arranged in mesas of the semiconductor body, the mesas being laterally confined at least by the control trenches.

21. The power semiconductor device of claim 20, wherein in the second section, at least some of the mesas are laterally confined by one of the first control trenches and by one of the second control trenches.

22. The power semiconductor device of claim 17, wherein at least some of the semiconductor channel structures comprise a respective source region of a first conductivity type electrically connected to the first load terminal, and wherein in the second section, the source regions are arranged adjacent to the first control electrodes and spatially displaced from the second control electrodes.

23. The power semiconductor device of claim 17, wherein the semiconductor body is formed in a single semiconductor chip.

24. The power semiconductor device of claim 17, wherein the active region further comprises a third section including a subset of the second control electrodes, the third section constituting a diode section such that the power semiconductor device exhibits an RC IGBT configuration.

25. A power semiconductor device, comprising:
a semiconductor body coupled to a first load terminal and a second load terminal;
an active region with a second section configured to conduct a load current between the first load terminal and the second load terminal;
electrically isolated from the first load terminal and the second load terminal, a plurality of first control electrodes in the second section, and a plurality of second control electrodes in the second section, wherein the first control electrodes are configured to be subjected to a first control signal and the second control electrodes are configured to be subjected to a second control signal; and
a plurality of semiconductor channel structures in the semiconductor body extending in the second section, each of the plurality of channel structures being associated to at least one of the first control electrodes, each of the semiconductor channel structures comprising a source region of a first conductivity type and a body region of a second conductivity type different from the first conductivity type, the body region separating the source region from a drift region of the first conductivity type, the respective at least one of the first control electrodes being configured to induce an inversion channel within the body region of the associated channel structure contributing to the load current,
wherein in the second section, a voltage of the second control signal influences the inversion channels controlled by the first control electrodes.

26. A power semiconductor device, comprising:
a semiconductor body coupled to a first load terminal and a second load terminal;
an active region with a second section configured to conduct a load current between the first load terminal and the second load terminal;
electrically isolated from the first load terminal and the second load terminal, a plurality of first control electrodes in the second section, and a plurality of second control electrodes in the second section, wherein the first control electrodes are arranged in first control trenches and insulated from the semiconductor body by a first trench insulator and configured to be subjected to a first control signal, and the second control electrodes are arranged in second control trenches and insulated from the semiconductor body by a second trench insulator and configured to be subjected to a second control signal; and
a plurality of semiconductor channel structures in the semiconductor body extending in the second section, each of the plurality of channel structures being associated to at least one of the first control electrodes,
wherein each of the semiconductor channel structures comprises a source region of a first conductivity type and a body region of a second conductivity type different from the first conductivity type, the body region separating the source region from a drift region of the first conductivity type,
wherein the respective at least one of the first control electrodes is configured to induce an inversion channel within the body region of the associated channel structure contributing to the load current,
wherein the semiconductor channel structures are arranged in mesas of the semiconductor body, the mesas being laterally confined at least by the control trenches,
wherein in the second section, at least some of the mesas comprising channel structures are laterally confined by one of the first control trenches and by one of the second control trenches.

27. A method of operating a half bridge circuit comprising a first power semiconductor device according to claim 24 and a second power semiconductor device according to claim 24, comprising:
providing a first control signal to the plurality of first control electrodes of the first power semiconductor device and a second control signal to the plurality of the second control electrodes of the first power semiconductor device; and
providing a further first control signal to the plurality of first control electrodes of the second power semiconductor device and a further second control signal to the plurality of the second control electrodes of the second power semiconductor device.
